(19) United States
(12) Patent Application Publication
(10) Pub. No.: US 2026/0324023 A1
(43) Pub. Date: Oct. 15, 2026

(54) SEMICONDUCTOR STRUCTURE WITH ROUGHENED SIDEWALL AND METHOD OF MANUFACTURING THEREOF

(71) Applicant: TAIWAN SEMICONDUCTOR MANUFACTURING COMPANY LTD., HSINCHU (TW)

(72) Inventor: JEN-YUAN CHANG, HSINCHU CITY (TW)

(21) Appl. No.: 19/711,994

(22) Filed: Jun. 18, 2026

Related U.S. Application Data
(62) Division of application No. 17/821,165, filed on Aug. 20, 2022, now Pat. No. 12,707,688.

(51) Int. Cl. H10D 62/50; H10W 90/00

(52) U.S. Cl. CPC H10D 62/50; H10W 90/00; H10W 90/732

(57) ABSTRACT

A semiconductor structure includes a die structure including: a substrate having a sidewall; a dielectric disposed over the substrate; an interconnect structure disposed within the dielectric; and a capping member surrounding the die structure, wherein the sidewall of the substrate includes a plurality of recesses extending into the substrate, and each of the plurality of recesses surrounds at least a portion of the capping member.

### CROSS-REFERENCE TO RELATED APPLICATIONS

This application is a divisional application of U.S. patent application Ser. No. 17/821,165 filed on Aug. 20, 2022, entitled of "SEMICONDUCTOR STRUCTURE WITH ROUGHENED SIDEWALL AND METHOD OF MANUFACTURING THEREOF ", which is incorporated herein by reference in their entireties.

### BACKGROUND

The semiconductor industry has experienced rapid growth due to ongoing improvements in the integration density of a variety of electrical components. To accommodate the miniaturized scale of the semiconductor device, various technologies and applications have been developed for the wafer-level packaging, involving greater numbers of different components with different functions. Improvement in integration density has resulted from iterative reduction of minimum feature size, which allows more components to be integrated into a given area.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure in accordance with some embodiments of the present disclosure.

FIG. 2 is a cross-sectional view of a semiconductor structure in accordance with another embodiment of the present disclosure.

FIG. 3 is a cross-sectional view of a semiconductor structure in accordance with another embodiment of the present disclosure.

FIG. 4 is a cross-sectional view of a semiconductor structure in accordance with another embodiment of the present disclosure.

FIG. 5 is an enlarged view of an embodiment of a portion AA in any one FIGS. 1 to 4.

FIG. 6 is an enlarged view of an embodiment of a portion AA in any one FIGS. 1 to 4.

FIG. 7 is an enlarged view of an embodiment of a portion AA in any one FIGS. 1 to 4.

FIG. 8 is an enlarged view of an embodiment of a portion AA in any one FIGS. 1 to 4.

FIG. 9 is an enlarged view of an embodiment of a portion AA in any one FIGS. 1 to 4.

FIG. 10 is an enlarged view of an embodiment of a portion AA in any one FIGS. 1 to 4.

FIG. 11 is a flow diagram of a method of manufacturing a semiconductor structure in accordance with some embodiments of the present disclosure.

FIGS. 12 to 25 are cross-sectional views of one or more stages of the method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as "first," "second" and "third" describe various elements, components, regions, layers and/or sections, these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" and “about” generally mean within a value or range that can be contemplated by people having ordinary skill in the art. Alternatively, the terms "substantially," "approximately" and "about" mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms "substantially," "approximately" or "about." Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In the present disclosure, a semiconductor structure and a method of manufacturing a semiconductor structure are provided. The semiconductor structure includes a die structure having a roughened sidewall covered by a capping member. Other features and processes may also be included. In some embodiments, the method of manufacturing the semiconductor structure includes forming a roughened sidewall for a die structure and forming a capping member to cover the roughened sidewall. As a result, adhesion between the die structure and the capping member is increased or improved. Delamination of the capping member from the die structure is minimized or avoided. The overall strength of the semiconductor structure is also increased or improved.

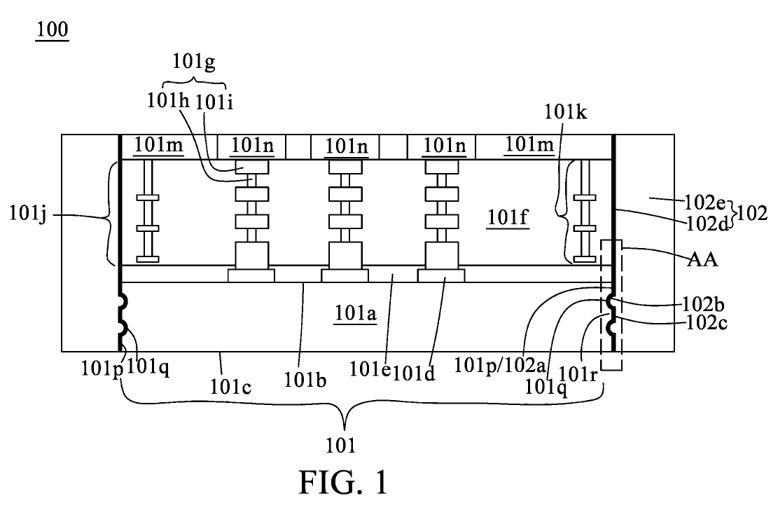

FIG. 1 is a schematic cross-sectional view of a first semiconductor structure 100 in accordance with some embodiments of the present disclosure. In some embodiments, the first semiconductor structure 100 includes a die structure 101 and a capping member 102 surrounding the die structure 101. The first semiconductor structure 100 is a chip, a package or a part of the chip or the package. In some embodiments, the die structure 101 is a die, a chip or a package. In some embodiments, the die structure 101 is a logic die, a central processing unit (CPU) die, a micro control unit (MCU) die, an input-output (IO) die, an application processor (AP) die, or the like. The die structure 101 includes a substrate 101a, a die pad 101d, a passivation 101e, a dielectric 101f, and an interconnect structure 101g. The die structure 101 is surrounded by the capping member 102.

The substrate 101a includes semiconductive material such as silicon, germanium, gallium, arsenic, or a combination thereof. In some embodiments, the substrate 101a is a semiconductor wafer. In some embodiments, the substrate 101a is a silicon substrate. The substrate 101a includes a first surface 101b and a second surface 101c opposite to the first surface 101b. In some embodiments, the first surface 101b is a front side or an active side that several electrical components are disposed thereon. In some embodiments, the second surface 101c is a back side or an inactive side that electrical component disposed thereon is absent.

The substrate 101a has a sidewall 101p extending between the first surface 101b and the second surface 101c. In some embodiments, the sidewall 101p has a roughness that the sidewall 101p is not a planar surface. In some embodiments, the roughness is formed by etching or any other suitable operation. In some embodiments, the sidewall 101p is a roughened sidewall.

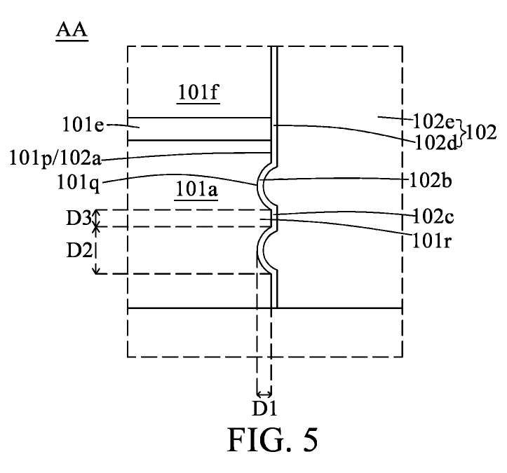

FIG. 5 is an enlarged view of a portion AA of FIG. 1 illustrating the sidewall 101p of the substrate 101a. Referring to FIG. 5, the sidewall 101p includes several recesses 101q extending into the substrate 101a. A number of the recesses 101q present along the sidewall 101p is more than one. In some embodiments, the number of the recesses 101q is three. Each of the recesses 101q has a depth D1 of greater than or equal to 0.5um. In some embodiments, the depth D1 is about 1um. Each of the recesses 101q has a width D2 of greater than 0.1um. In some embodiments, the width D2 is about 2um. The recesses 101q are spaced from each other in a distance D3 of greater than 0.1um. In some embodiments, the distance D3 is about 1um. In some embodiments, the sidewall 10p of the substrate 101a has several protrusions 101r protruded from the substrate 101a. The protrusions 101r are alternately disposed with the recesses 101q.

Referring back to FIG. 1, the die pad 101d is disposed on the substrate 101a. In some embodiments, the die pad 101d is disposed on the first surface 101b of the substrate 101a. The die pad 101d is configured to receive an external interconnect structure, so that the substrate 101a or the electrical components on or within the substrate 101a can electrically connect to the external interconnect structure via the die pad 101d. The die pad 101d includes conductive material such as aluminum or the like.

The passivation 101e is disposed on the substrate 101a and surrounds the die pad 101d. In some embodiments, the passivation 101e is disposed on the first surface 101b of the substrate 101a. The die pad 101d is at least partially exposed through the passivation 101e. The passivation 101e includes dielectric material such as silicon oxide, silicon nitride, silicon carbide, silicon oxynitride or the like.

The dielectric 101f is disposed on the passivation 101e. In some embodiments, the dielectric 101f is disposed over the first surface 101b of the substrate 101a. The dielectric 101f includes dielectric material such as polymer, polyimide, polybenzoxazole (PBO) or the like. The interconnect structure 101g is disposed within the dielectric 101f. The interconnect structure 101g is electrical routing within the die structure 101. The interconnect structure 101g is electrically coupled with the die pad 101d. The interconnect structure 101g extends from the die pad 101d and away from the substrate 101. The interconnect structure 101g includes conductive material such as copper, silver or the like. In some embodiments, a sidewall of the dielectric 101f is disposed above and substantially coplanar with the sidewall 101p of the substrate 101a. In some embodiments, an inter-metal dielectric (IMD) 101j comprising the dielectric 101f and the interconnect structure 101g is disposed over the substrate 101a.

In some embodiments, the interconnect structure 101g includes a via portion 101h and a pad portion 101i coupled with the via portion 101h. The via portion 101h extends vertically within the dielectric 101f. The pad portion 101i extends laterally within the dielectric 101f. The pad portion 101i is coupled with the die pad 101d. In some embodiments, the interconnect structure 101g includes a seal ring member 101k disposed adjacent to a periphery of the die structure 101. The seal ring member 101k surrounds the interconnect structure 101g. The seal ring member 101k extends vertically within the dielectric 101f. The seal ring member 101k is a dummy structure and is electrically isolated from the pad portion 101i, the via portion 101h, the die pad 101d, and an electrical component in the substrate 101a. In some embodiments, the seal ring member 101k is connected to an electrical ground.

The capping member 102 surrounds the die structure 101. The capping member 102 extends along and contacts a sidewall of the die structure 101. The capping member 102 is in contact with the substrate 101a, the passivation 101e, and the dielectric 101f. The capping member 102 includes organic polymeric material such as epoxy, molding compound, polyimide, resin or the like. In some embodiments, a portion of the capping member 102 is disposed within the recesses 101q of the sidewall 101p of the substrate 101a. Each of the recesses 101q of the substrate 101a surrounds at least a portion of the capping member 102.

The capping member 102 has a sidewall 102a contacting the sidewall 101p of the substrate 101a and the sidewall of the dielectric 101f. In some embodiments, the sidewall 102a of the capping member 102 is complementary with the sidewall 101p of the substrate 101a. Referring to FIG. 5, the sidewall 102a of the capping member 102 includes several protrusions 102b disposed within the recesses 101q of the substrate 101a correspondingly. The protrusions 102b are complementary with the recesses 101q. In some embodiments, the protrusions 102b of the capping member 102 are spaced apart from each other in the distance D3 of substantially greater than 0.1um.

The capping member 102 includes several recesses 102c surrounding the protrusions 101r of the substrate 101a correspondingly. The recesses 102c of the capping member 102 are complementary with the protrusions 101r of the substrate 101a. Since the sidewall 101p of the substrate 101a has the recesses 101q complementary with the protrusions 102b of the capping member 102, contact surface between the substrate 101a and the capping member 102 is increased or improved. Therefore, an adhesion between the substrate 101a and the capping member 102 is increased or improved. Delamination of the capping member 102 from the die structure 101 is minimized or avoided.

In some embodiments, the capping member 102 is a multilayers structure. In some embodiments, the capping member 102 includes a first layer 102d contacting the die structure 101, and a second layer 102e conformal to the first layer 102d. The first layer 102d is conformal to the entire sidewall 101p of the substrate 101a. In some embodiments, the first layer 102d is conformal to the recesses 101q and the protrusions 101r of the substrate 101a. The second layer 102e is at least partially disposed within the recesses 101q of the substrate 101a. In some embodiments, a fluidity of the first layer 102d is substantially greater than a fluidity of the second layer 102e. In some embodiments, a molecular chain length of the first layer 102d is substantially less than a molecular chain length of the second layer 102e. In some embodiments, a ratio of carbon to fluorine of the first layer 102d is different from a ratio of carbon to fluorine of the second layer 102e.

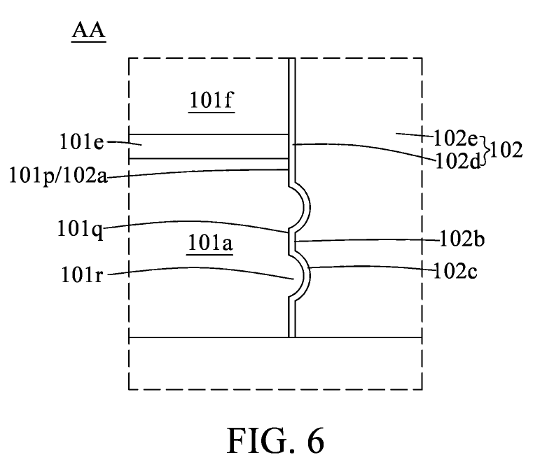

Alternatively, the sidewall 101p of the substrate 101a and the sidewall 102a of the capping member 102 are in configurations different from the embodiment shown in FIGS. 1 and 5. In some embodiments, the sidewall 101p of the substrate 101a and the sidewall 102a of the capping member 102 are in configurations as shown in FIG. 6. Referring to FIG. 6, the substrate 101 has several protrusions 101r protruded into corresponding recesses 102c.

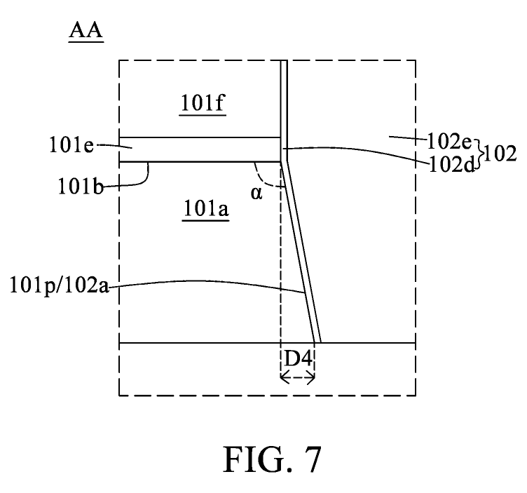

In some embodiments, the sidewall 101p of the substrate 101a and the sidewall 102a of the capping member 102 are in configurations as shown in FIG. 7. The sidewall 101p of the substrate 101a and the sidewall 102a of the capping member 102 are slanted sidewalls. In some embodiments, an interior angle α between the sidewall 101p and the first surface 101b of the substrate 101a is an obtuse angle. In some embodiments, a horizontal distance D4 between the sidewall 101p of the substrate 101a and a vertical line is substantially greater than 0.5um.

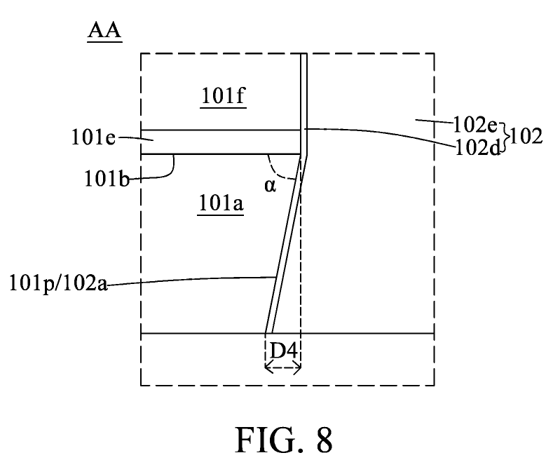

In some embodiments, the sidewall 101p of the substrate 101a and the sidewall 102a of the capping member 102 are in configurations as shown in FIG. 8. The sidewall 101p of the substrate 101a and the sidewall 102a of the capping member 102 are slanted sidewalls. In some embodiments, an interior angle α between the sidewall 101p and the first surface 101b of the substrate 101a is an acute angle. In some embodiments, a horizontal distance D4 between the sidewall 101p of the substrate 101a and a vertical line is substantially greater than 0.5um.

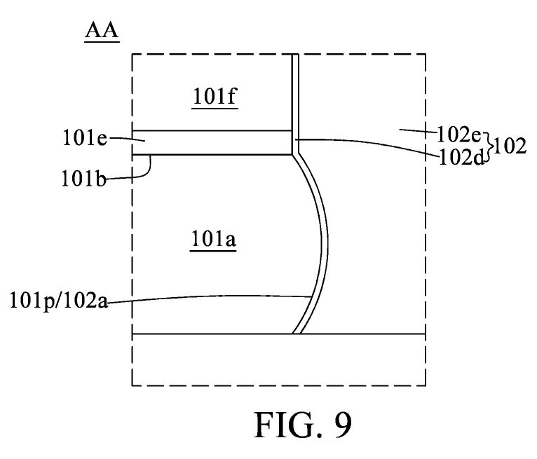

In some embodiments, the sidewall 101p of the substrate 101a and the sidewall 102a of the capping member 102 are in configurations as shown in FIG. 9. The sidewall 101p of the substrate 101a is a convex sidewall, while the sidewall 102a of the capping member 102 is a concave sidewall complementary with the sidewall 101p of the substrate 101a.

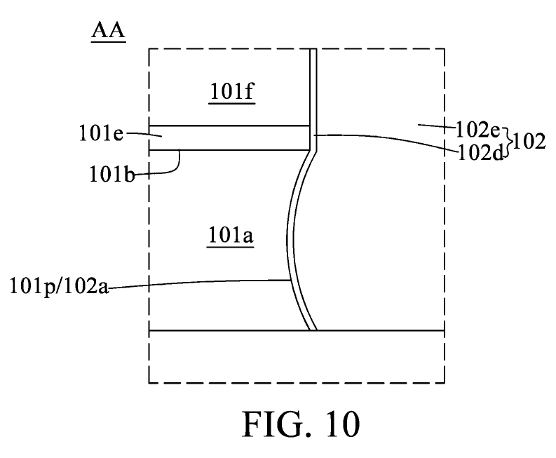

In some embodiments, the sidewall 101p of the substrate 101a and the sidewall 102a of the capping member 102 are in configurations as shown in FIG. 10. The sidewall 101p of the substrate 101a is a concave sidewall, while the sidewall 102a of the capping member 102 is a convex sidewall complementary with the sidewall 101p of the substrate 101a.

Referring back to FIG. 1, in some embodiments, a bonding dielectric 101m is disposed on disposed over the dielectric 101f of the die structure 101 and surrounded by the capping member 102. The capping member 102 is in contact with the bonding dielectric 101m, the dielectric 101f and the substrate 101a. The bonding dielectric 101m includes dielectric material such as oxide or the like. In some embodiments, the bonding dielectric 101m includes silicon oxide.

In some embodiments, a bonding pad 101n is disposed over the interconnect structure 101g and surrounded by the bonding dielectric 101m. The bonding pad 101n is at least partially exposed through the bonding dielectric 101m and is configured to receive an external interconnect structure. The bonding pad 101n is electrically connected with the interconnect structure 101g. The bonding pad 101n is electrically coupled with the pad portion 101i. The bonding pad 101n includes conductive material such as copper, silver or the like.

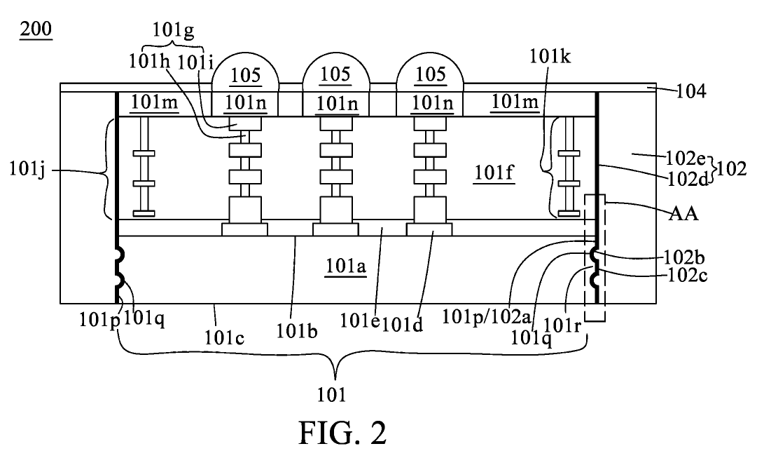

FIG. 2 is a schematic cross-sectional view of a second semiconductor structure 200 in accordance with some embodiments of the present disclosure. The second semiconductor structure 200 is similar to the first semiconductor structure 100 of FIG. 1, except a second passivation 104 is disposed over the capping member 102 and the bonding dielectric 101m, and a conductive bump 105 is disposed on the bonding pad 101n.

The second passivation 104 surrounds the conductive bump 105. The second passivation 104 includes dielectric material such as silicon oxide, silicon nitride, silicon carbide, silicon oxynitride or the like. The conductive bump 105 is protruded from the die structure 101. The conductive bump 105 is configured to mount on another die structure and electrically connect with an external interconnect structure or another die structure. In some embodiments, the conductive bump 105 is ball grid array (BGA) balls, controlled collapse chip connection (C4) bumps, microbumps, pillars or the like. The conductive bump 105 includes metals such as lead, tin copper, gold, nickel, etc. or metal alloy such as combination of lead, tin copper, gold, nickel, etc.

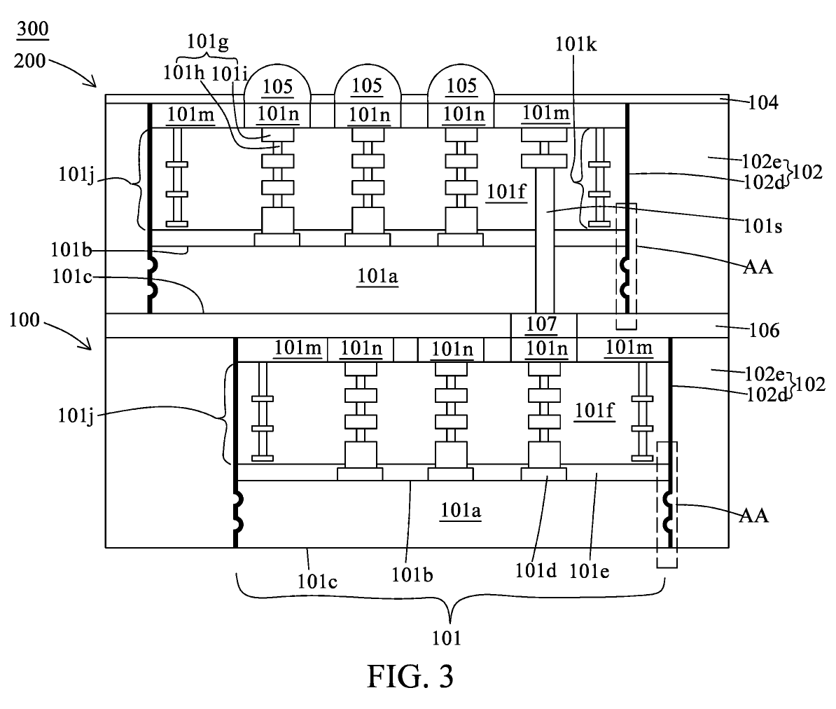

FIG. 3 is a schematic cross-sectional view of a third semiconductor structure 300 in accordance with some embodiments of the present disclosure. The third semiconductor structure 300 includes the first semiconductor structure 100 and the second semiconductor structure 200 stacked over the first semiconductor structure 100. The first semiconductor structure 100 is similar to the one illustrated in FIG. 1 and discussed above. The second semiconductor structure 200 is similar to the one illustrated in FIG. 2 and discussed above.

In some embodiments, the second semiconductor structure 200 further includes a via 101s extending partially through the dielectric 101f and extending through the substrate 101a. The via 101s is electrically coupled with the pad portion 101i or the via portion 101h of the interconnect structure 101g. The via 101s is at least partially exposed through the second surface 101c of the substrate 101a.

The third semiconductor structure 300 includes a second bonding dielectric 106 between the first semiconductor structure 100 and the second semiconductor structure 200, and a second bonding pad 107 surrounded by the second bonding dielectric 106. The second bonding dielectric 106 bonds with the bonding dielectric 101m of the first semiconductor structure 100, and the second bonding pad 107 bonds with the bonding pad 101n of the first semiconductor structure 100. The via 101s is electrically coupled with the second bonding pad 107. In some embodiments, the die structure 101 of the first semiconductor structure 100 is electrically coupled with the die structure 101 of the second semiconductor structure 200 through the bonding pad 101n of the first semiconductor structure 100, the via 101s and the second bonding pad 107. In some embodiments, the die structure 101 of the second semiconductor structure 200 is horizontally shifted from the die structure 101 of the first semiconductor structure 100.

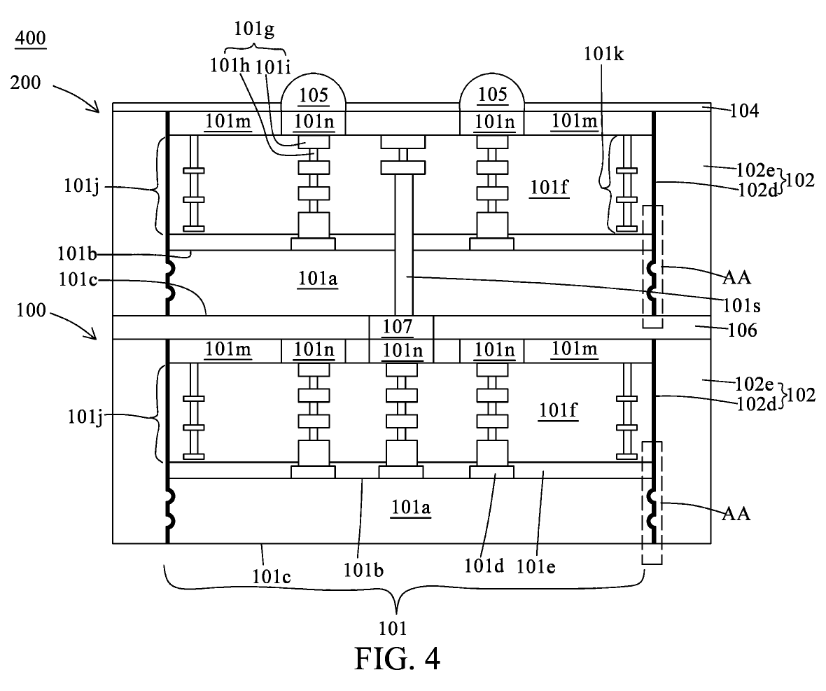

FIG. 4 is a schematic cross-sectional view of a fourth semiconductor structure 400 in accordance with some embodiments of the present disclosure. The fourth semiconductor structure 400 includes the first semiconductor structure 100 and the second semiconductor structure 200 stacked over the first semiconductor structure 100. The first semiconductor structure 100 is similar to the one illustrated in FIGS. 1 or 3 and discussed above. The second semiconductor structure 200 is similar to the one illustrated in FIG. 2 or 3 and discussed above. The fourth semiconductor structure 400 is similar to the third semiconductor structure 300, except the die structure 101 of the first semiconductor 100 is aligned with the die structure 101 of the second semiconductor structure 200. In some embodiments, the capping member 102 of the first semiconductor structure 100 is also aligned with the capping member 102 of the second semiconductor structure 200.

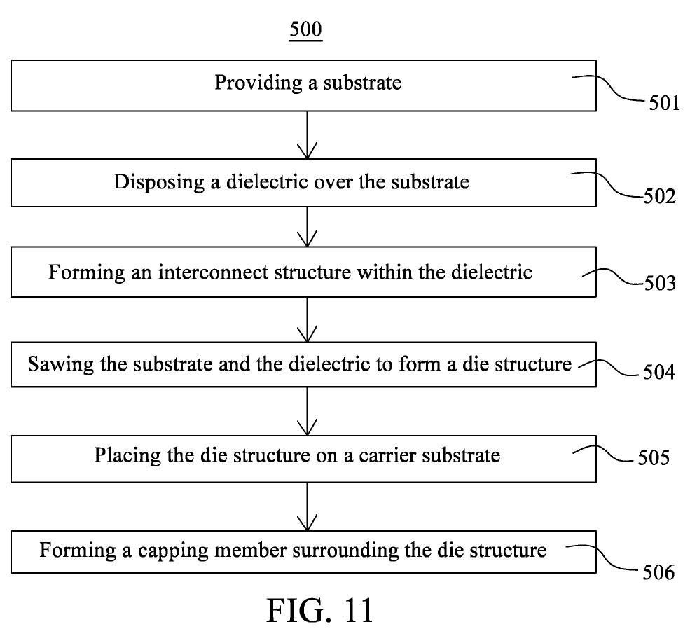

In the present disclosure, a method of manufacturing a semiconductor structure (100, 200, 300 or 400) is also disclosed. In some embodiments, the semiconductor structure (100, 200, 300 or 400) is formed by a method 500. The method 500 includes a number of operations and the description and illustration are not deemed as a limitation as the sequence of the operations. FIG. 11 is an embodiment of the method 500 of manufacturing the semiconductor structure (100, 200, 300 or 400). The method 500 includes a number of operations (501, 502, 503, 504, 505 and 506).

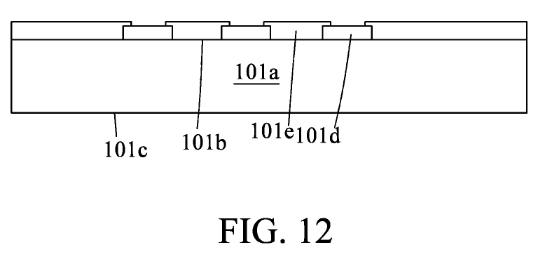

In operation 501, a substrate 101a is provided as shown in FIG. 12. The substrate 101a is a semiconductor wafer. In some embodiments, the substrate 101a is a silicon substrate. The substrate 101a includes a first surface 101b and a second surface 101c opposite to the first surface 101b. In some embodiments, the substrate 101a has similar configurations as the one illustrated in any one of FIGS. 1 to 4 and discussed above.

A die pad 101d is disposed on the substrate 101a, configured to receive an external interconnect structure, and includes conductive material such as aluminum or the like. A passivation 101e is disposed on the substrate 101a and surrounds the die pad 101d. The die pad 101d is at least partially exposed through the passivation 101e.The passivation 101e includes dielectric material such as silicon oxide, silicon nitride, silicon carbide, silicon oxynitride or the like. In some embodiments, the die pad 101d and the passivation 101e have similar configurations as those illustrated in any one of FIGS. 1 to 4 and discussed above.

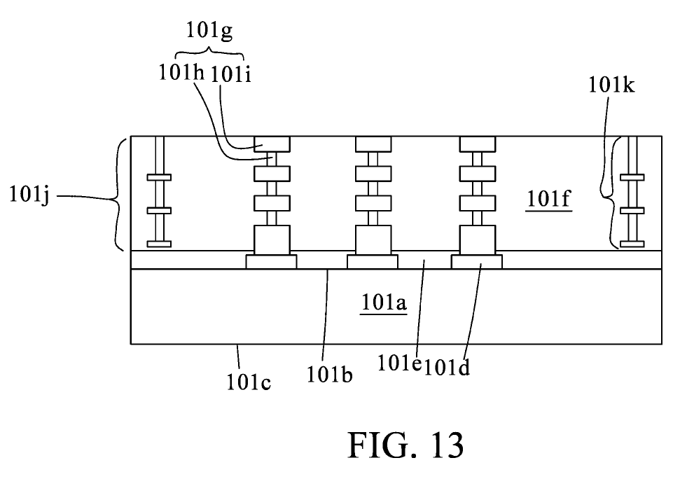

In operation 502, a dielectric 101f is disposed over the substrate 101a as shown in FIG. 13. The dielectric 101f covers the passivation 101e. The dielectric 101f is disposed by deposition, chemical vapor deposition (CVD) or any other suitable operations. In some embodiments, the dielectric 101f has similar configurations as the one illustrated in any one of FIGS. 1 to 4 and discussed above.

In operation 503, an interconnect structure 101g is formed within the dielectric 101f as shown in FIG. 13. The interconnect structure 101g is formed by removing some portions of the dielectric 101f, and then disposing conductive material surrounded by the dielectric 101f. The portions of the dielectric 101f are removed by photolithography, etching or any other suitable operations. The conductive material is disposed by electroplating, sputtering or any other suitable operations. In some embodiments, the interconnect structure 101g is electrically coupled with the die pad 101d. In some embodiments, a pad portion 101i of the interconnect structure 101g is at least partially exposed through the dielectric 101f. In some embodiments, the interconnect structure 101g has similar configurations as the one illustrated in any one of FIGS. 1 to 4 and discussed above.

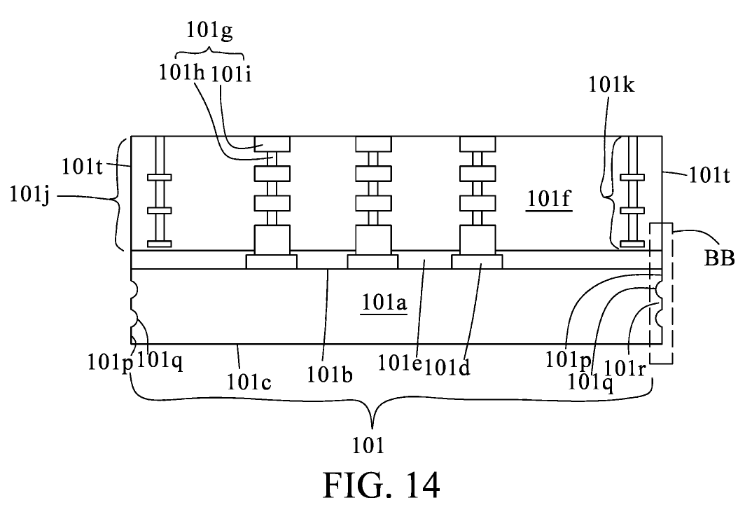

In operation 504, the substrate 101a and the dielectric 101f are sawn to form a die structure 101 as shown in FIG. 14. The substrate 101a and the dielectric 101f are sawn along a sidewall 101t of the dielectric 101f and a sidewall 101p of the substrate 101a to form the die structure 101. In some embodiments, the substrate 101a and the dielectric 101f are sawn by etching, singulation, die sawing or any other suitable operations. The sawing of the substrate 101a and the dielectric 101f includes removing a portion of the dielectric 101f along the sidewall 101t by etching, and then removing a first portion of the substrate 101a along the sidewall 101p by etching. In some embodiments, the sawing of the dielectric 101f is prior to the sawing of the substrate 101a. A sidewall 101p of the substrate 101a and a sidewall 101t of the dielectric 101f are formed after the sawing of the substrate 101a and the dielectric 101f. The sidewall 101p of the substrate 101a extends between the first surface 101b and the second surface 101c of the substrate 101a.

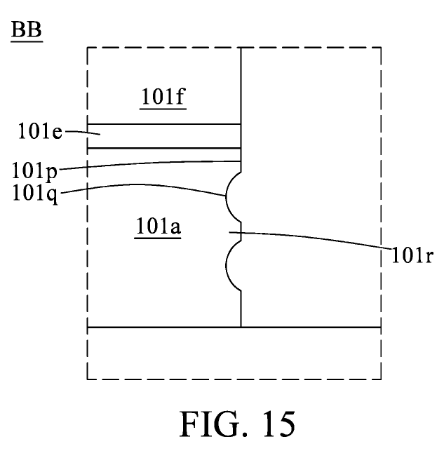

In some embodiments, the sawing of the substrate 101a includes forming the sidewall 101p of the substrate 101a having several recesses 101q extending into the substrate 101a as shown in FIG. 14. After the removal of the portion of the dielectric 101f and the first portion of the substrate 101a, a second portion of the substrate 101a is further removed to form several recesses 101q indented into the substrate 101a as shown in FIG. 14. FIG. 15 is an enlarged view of a portion BB of FIG. 14 illustrating the recesses 101q formed along the sidewall 101p of the substrate 101a. In some embodiments, the sidewall 101p of the substrate 101a is a smooth or planar surface before the formation of the recesses 101q. The sidewall 101p of the substrate 101a becomes a roughened surface after the formation of the recesses 101q.

In some embodiments, the recesses 101p are formed by dry etching. In some embodiments, the recesses 101p are formed by dry reactive ion etching (DRIE), Bosch etching or any other suitable operations. After the removal of the first portion of the substrate 101a, a polymeric layer is disposed over the dielectric 101f and conformal to the sidewall 101p. In some embodiments, the polymeric layer includes fluorocarbon plasma such as C₄F₈ or the like.

After the deposition of the polymeric layer, a bottom portion of the polymeric layer is removed to expose a portion of the sidewall 101p of the substrate 101a. In some embodiments, the bottom portion of the polymeric layer is removed by anisotropic etching. The exposed portion of the sidewall 101p is then removed to form the recess 101q. In some embodiments, the exposed portion of the sidewall 101p is removed by isotropic etching. In some embodiments, the exposed portion of the sidewall 101p is removed by SF₆ plasma. The deposition of the polymeric layer, the removal of the bottom portion of the polymeric layer, and the removal of the exposed portion of the sidewall 101p of the substrate 101a are repeated sequentially to form the recesses 101p along the sidewall 101p as shown in FIGS. 14 and 15. The die structure 101 is formed after the formation of the recesses 101p.

In some embodiments, the sidewall 101p is processed to become a slanted sidewall as shown in FIG. 7 or 8 by etching operations, instead of the formation of the recesses 101q. A portion of the sidewall 101p of the substrate 101a is removed to become the slanted sidewall. In some embodiments, the sidewall 101p is processed to become a convex or concave sidewall as shown in FIGS. 9 or 10 by etching operations, instead of the formation of the recesses 101q. A portion of the sidewall 101p of the substrate 101a is removed to become the convex or concave sidewall.

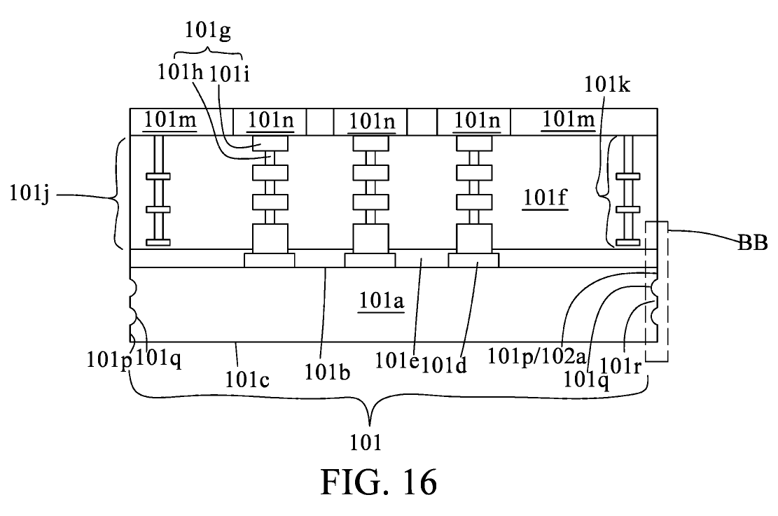

In some embodiments, a bonding dielectric 101m and a bonding pad 101n are formed over the dielectric 101f after the operation 504, as shown in FIG. 16. The bonding dielectric 101m is disposed over the dielectric 101f by deposition or any other suitable operations. A portion of the bonding dielectric 101m is removed, and then the bonding pad 101n is formed and surrounded by the bonding dielectric 101m. The bonding pad 101n is formed by electroplating, sputtering or any other suitable operations. The bonding pad 101n is electrically coupled with the interconnect structure 101g. In some embodiments, the bonding dielectric 101m and the bonding pad 101n have similar configurations as those illustrated in any one of FIGS. 1 to 4 and discussed above.

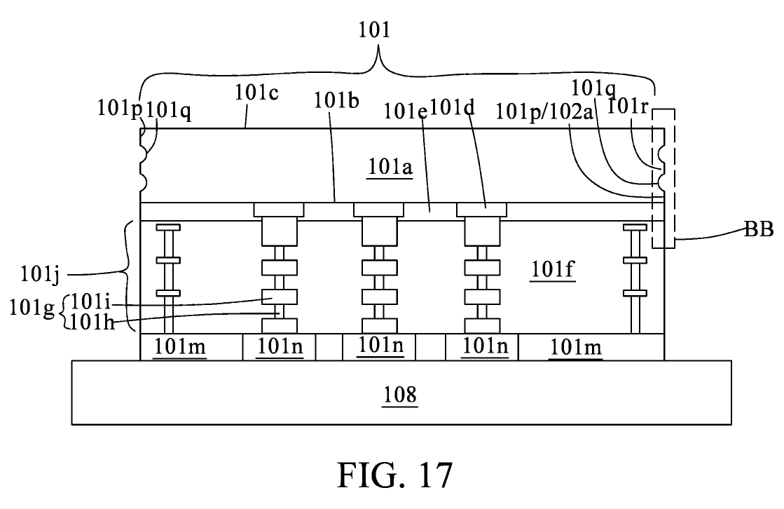

In operation 505, the die structure 101 is placed on a carrier substrate 108 as shown in FIG. 17. The carrier substrate 108 is configured to temporarily support a substrate or device thereon. The carrier substrate 108 is a blank glass, ceramic, silicon or the like. In some embodiments, the die structure 101 is flipped and then placed on the carrier substrate 108.

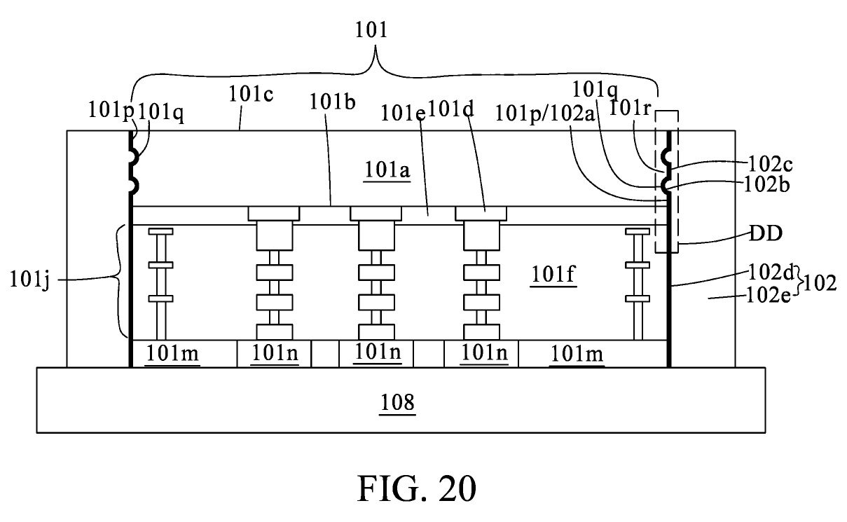

In operation 506, a capping member 102 is formed as shown in FIG. 20. The capping member 102 surrounds the die structure 101. In some embodiments, the capping member 102 is formed by disposing a polymeric material surrounding the die structure 101 and conformal to the sidewall 101p and the recesses 101q of the substrate 101a. In some embodiments, the capping member 102 is formed by disposing the polymeric material over the second surface 101c of the substrate 101a, over the carrier substrate 108, and contacting the sidewall 101p and the recesses 101q of the substrate 101a. After the disposing of the polymeric material, some portions of the polymeric material on the second surface 101c of the substrate 101a are removed by planarization or any other suitable operations. In some embodiments, the polymeric material is an organic polymeric material such as epoxy, molding compound, polyimide, resin or the like.

In some embodiments, a sidewall 102a of the capping member 102 is complementary with the sidewall 101p of the substrate 101a. The sidewall 102a of the capping member 102 includes several protrusions 102b disposed within the recesses 101q of the substrate 101a correspondingly. The protrusions 102b are complementary with the recesses 101q. Since the sidewall 101p of the substrate 101a has the recesses 101q complementary with the protrusions 102b of the capping member 102, contact surface between the substrate 101a and the capping member 102 is increased or improved. Therefore, an adhesion between the substrate 101a and the capping member 102 is increased or improved. Delamination of the capping member 102 from the die structure 101 is minimized or avoided.

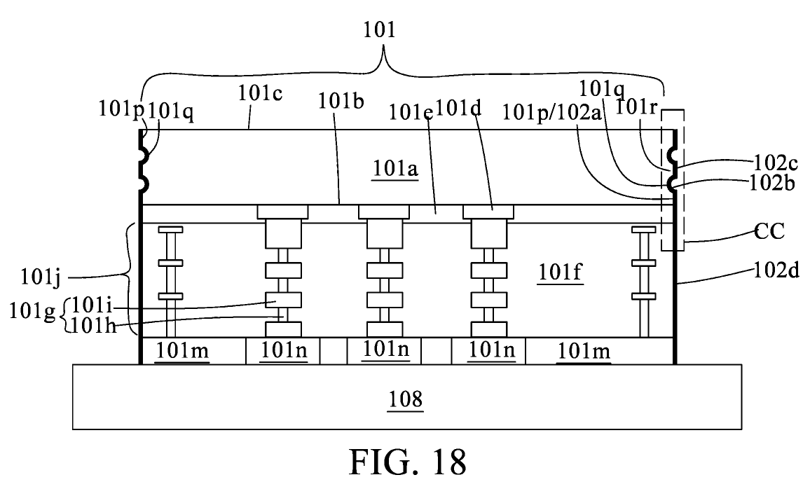

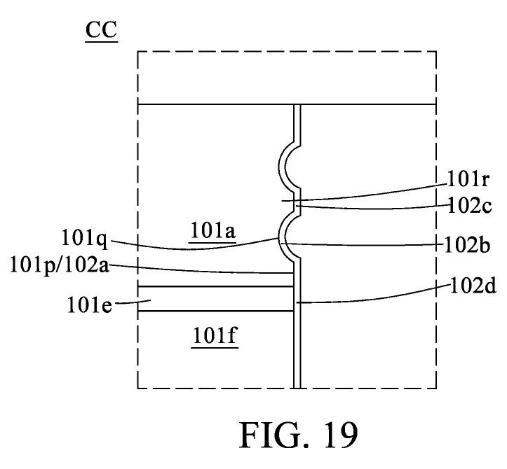

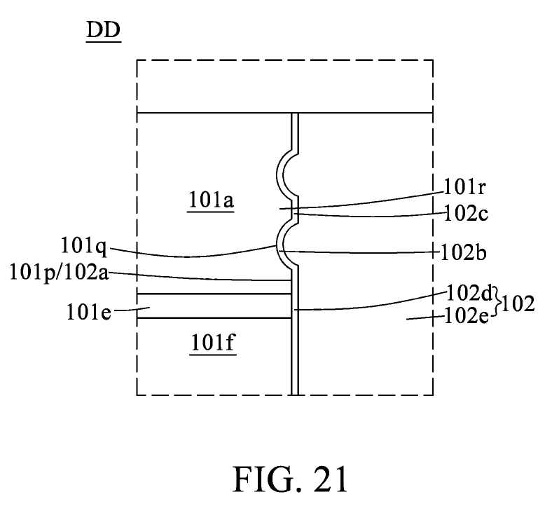

In some embodiments, the capping member 102 is formed by disposing a first polymeric material 102d conformal to the sidewall 101p of the substrate 101a as shown in FIG. 18, and disposing a second polymeric material 102e conformal to the first polymeric material 102d and within the recesses 101q as shown in FIG. 20. FIG. 19 is an enlarged view of a portion CC in FIG. 18, and FIG. 21 is an enlarged view of a portion DD in FIG. 20. In some embodiments, a fluidity of the first polymeric material 102d is substantially greater than a fluidity of the second polymeric material 102e. In some embodiments, a molecular chain length of the first polymeric material 102d is substantially less than a molecular chain length of the second polymeric material 102e. In some embodiments, a ratio of carbon to fluorine of the first polymeric material 102d is different from a ratio of carbon to fluorine of the second polymeric material 102e.

In some embodiments, the first polymeric material 102d is disposed over the second surface 101c of the substrate 101a, along the sidewall 101p of the substrate 101a, and conformal to the recesses 101q. After the disposing of the first polymeric material 102d, the second polymeric material 102e is disposed over and surrounding the first polymeric material 102d. The second polymeric material 102e is also disposed over the second surface 101c of the substrate 101a.

In some embodiments, after the disposing of the first polymeric material 102d and the second polymeric material 102e, some portions of the first polymeric material 102d and the second polymeric material 102e disposed over the second surface 101c of the substrate 101a are removed by planarization or any other suitable operations. In some embodiments, the first polymeric material 102d and the second polymeric material 102e have similar configurations as the first layer 102d and the second layer 102e illustrated in any one of FIGS. 1 to 4 and discussed above.

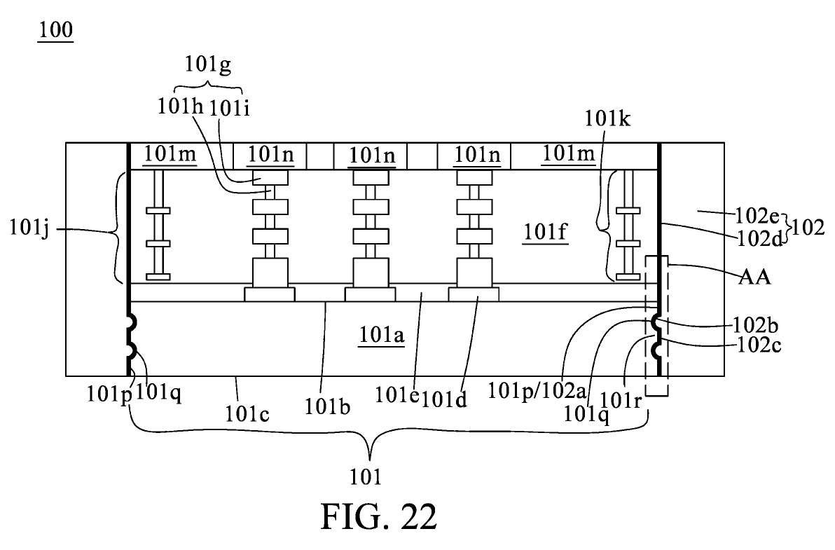

After the formation of the capping member 102, the die structure 101 and the capping member 102 are detached from the carrier substrate 108 as shown in FIG. 22. A first semiconductor structure 100 as shown in FIG. 22 is formed, which is similar to the one illustrated in FIG. 1.

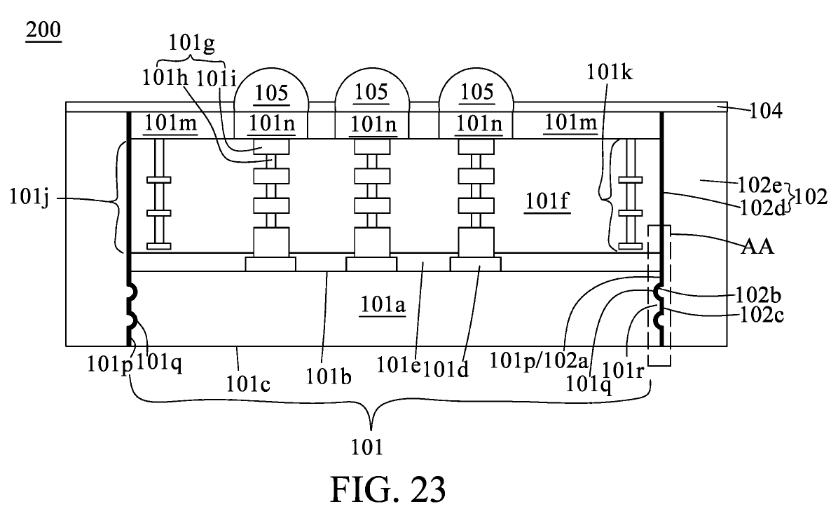

In some embodiments, a conductive bump 105 is disposed on the bonding pad 101n as shown in FIG. 23. The conductive bump 105 is disposed by electroplating, solder pasting, ball placement or any other suitable operations. A second semiconductor structure 200 as shown in FIG. 23 is formed, which is similar to the one illustrated in FIG. 2.

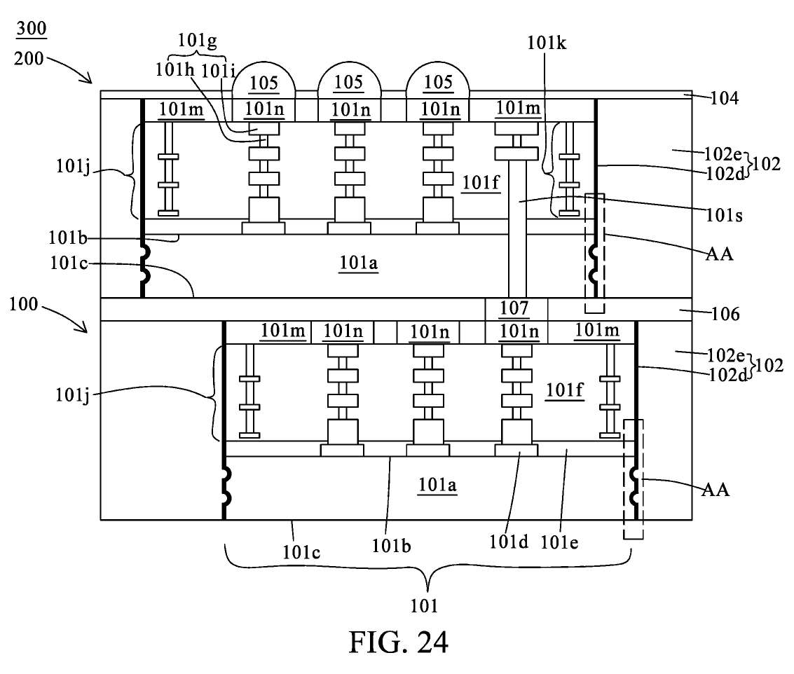

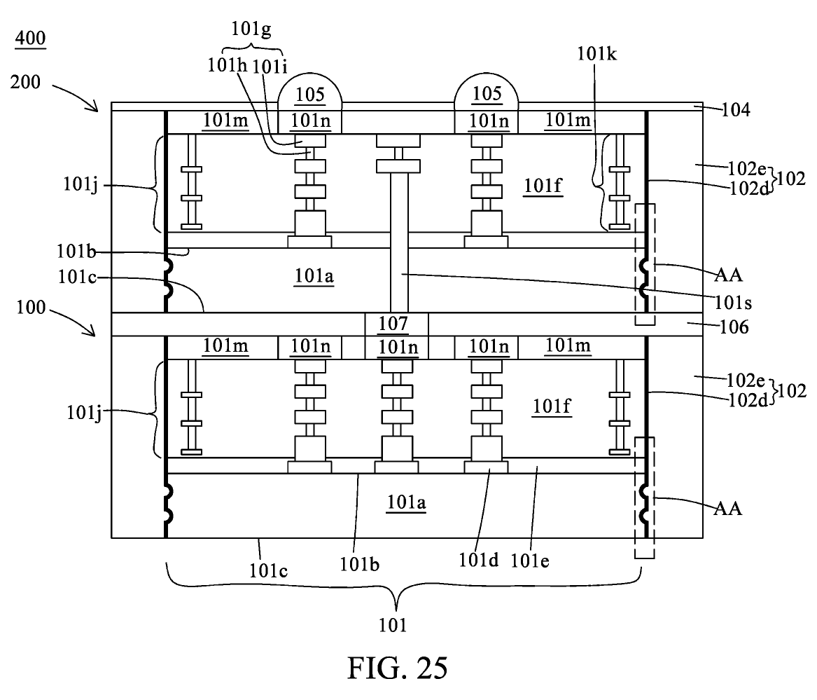

In some embodiments, after the formation of the first semiconductor structure 100 as shown in FIG. 22, the operations 501 to 506 are repeatedly implemented to form another semiconductor structure similar to the first semiconductor structure 100. After the formation of the another semiconductor structure, the another semiconductor structure is bonded over the first semiconductor structure 100 by hybrid bonding or the like to form a third semiconductor structure 300 as shown in FIG. 24 or a fourth semiconductor structure 400 as shown in FIG. 25.

In some embodiments, the hybrid bonding is formed by bonding the bonding dielectric 101m with a second bonding dielectric 106, and bonding the bonding pad 101n with a second bonding pad 107. In some embodiments, the second bonding dielectric 106 is disposed between the capping members 102 of the first semiconductor structure 100 and the another semiconductor structure. The third semiconductor structure 300 is similar to the one illustrated in FIG. 3. The fourth semiconductor structure 400 is similar to the one illustrated in FIG. 4.

One aspect of this disclosure relates to a method of manufacturing a semiconductor structure. The method includes providing a substrate disposing a dielectric over the substrate; forming an interconnect structure within the dielectric; sawing the substrate and the dielectric to form a first die structure; placing the first die structure on a carrier substrate; and forming a capping member surrounding the first die structure, wherein the sawing of the substrate includes forming a sidewall of the substrate having a plurality of recesses extending into the substrate, and wherein the sidewall of the substrate is coplanar with a sidewall of the dielectric.

In some embodiments, the formation of the capping member includes disposing a first polymeric material conformal to the sidewall of the substrate; and disposing a second polymeric material conformal to the first polymeric material and within the plurality of recesses. In some embodiments, a fluidity of the first polymeric material is substantially greater than a fluidity of the second polymeric material. In some embodiments, the plurality of recesses are formed by deep reactive ion etching (DRIE) operation. In some embodiments, the plurality of recesses are formed by Bosch etching operation. In some embodiments, the sawing of the dielectric is prior to the sawing of the substrate. In some embodiments, the method further comprises removing the capping member covering a back surface of the substrate, wherein the back surface faces away from the dielectric. In some embodiments, the sidewall of the substrate further comprises a planar surface between the two adjacent recesses. In some embodiments, the method further comprises stacking the first die structure on a second die structure, wherein the first die structure is vertically aligned with the second die structure. In some embodiments, the method further comprises stacking the first die structure on a second die structure, wherein the first die structure is vertically offset from the second die structure.

Another aspect of this disclosure relates to a method of manufacturing a semiconductor structure. The method includes providing a substrate having a first sidewall; disposing a dielectric over the first surface of the substrate, the dielectric having a second sidewall; sawing the first sidewall of the substrate and the second sidewall of the dielectric to form a die structure; and forming a capping member over the first die, wherein the first sidewall is not in parallel to the second sidewall.

In some embodiments, the first sidewall of the substrate is a slanted sidewall. In some embodiments, the first sidewall of the substrate is a convex sidewall or a concave sidewall. In some embodiments, the forming the capping member further comprises: forming a first layer conformally covering the slanted sidewall of the substrate; and forming a second layer conformally covering the slanted sidewall of the substrate, wherein a ratio of carbon to fluorine of the first layer is different from a ratio of carbon to fluorine of the second layer. In some embodiments, the method further comprises: forming a bonding dielectric disposed over the dielectric of the die structure and surrounded by the capping member; and forming a bonding pad disposed over the dielectric of the die structure, coupled with the interconnect structure, and surrounded by the bonding dielectric. In some embodiments, the method further comprises disposing a conductive pad on the bonding pad.

Another aspect of this disclosure relates to a method of manufacturing a semiconductor structure. The method includes providing a substrate; disposing a dielectric over the substrate; forming a plurality of recesses on a sidewall of the substrate, wherein the plurality if recesses extend into the substrate; and forming a first capping layer over the sidewall of the substrate, the first capping layer being conformal to the sidewall of the substrate; and forming a second capping layer over the first capping layer, the second capping layer being conformal to the first capping layer and separated from the substrate by the first layer.

In some embodiments, the first capping member includes a plurality of protrusions complementary with the plurality of recesses of the substrate. In some embodiments, the plurality of recesses are spaced from each other in a distance substantially greater than 0.1um. In some embodiments, the method further comprising forming the first capping layer over a sidewall of the dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor structure, comprising:
providing a substrate;
disposing a dielectric over the substrate;
forming an interconnect structure within the dielectric;
sawing the substrate and the dielectric to form a first die structure;
placing the first die structure on a carrier substrate; and
forming a capping member surrounding the first die structure,
wherein the sawing of the substrate includes forming a sidewall of the substrate having a plurality of recesses extending into the substrate, and
wherein the sidewall of the substrate is coplanar with a sidewall of the dielectric.

2. The method of claim 1, wherein the formation of the capping member includes disposing a first polymeric material conformal to the sidewall of the substrate; and disposing a second polymeric material conformal to the first polymeric material and within the plurality of recesses.

3. The method of claim 2, wherein a fluidity of the first polymeric material is substantially greater than a fluidity of the second polymeric material.

4. The method of claim 1, wherein the plurality of recesses are formed by deep reactive ion etching (DRIE) operation.

5. The method of claim 1, wherein the plurality of recesses are formed by Bosch etching operation.

6. The method of claim 1, wherein the sawing of the dielectric is prior to the sawing of the substrate.

7. The method of claim 1, further comprising removing the capping member covering a back surface of the substrate, wherein the back surface faces away from the dielectric.

8. The method of claim 1, wherein the sidewall of the substrate further comprises a planar surface between the two adjacent recesses.

9. The method of claim 1, further comprising stacking the first die structure on a second die structure, wherein the first die structure is vertically aligned with the second die structure.

10. The method of claim 1, further comprising stacking the first die structure on a second die structure, wherein the first die structure is vertically offset from the second die structure.

11. A method of manufacturing a semiconductor structure, comprising:
providing a substrate having a first sidewall;
disposing a dielectric over the first surface of the substrate, the dielectric having a second sidewall;
sawing the first sidewall of the substrate and the second sidewall of the dielectric to form a die structure; and
forming a capping member over the first die,
wherein the first sidewall is not in parallel to the second sidewall.

12. The method of claim 11, wherein the first sidewall of the substrate is a slanted sidewall.

13. The method of claim 11, wherein the first sidewall of the substrate is a convex sidewall or a concave sidewall.

14. The method of claim 11, wherein the forming the capping member further comprises:
forming a first layer conformally covering the slanted sidewall of the substrate; and
forming a second layer conformally covering the slanted sidewall of the substrate,
wherein a ratio of carbon to fluorine of the first layer is different from a ratio of carbon to fluorine of the second layer.

15. The method of claim 11, further comprising:
forming a bonding dielectric disposed over the dielectric of the die structure and surrounded by the capping member; and
forming a bonding pad disposed over the dielectric of the die structure, coupled with the interconnect structure, and surrounded by the bonding dielectric.

16. The method of claim 15, further comprising disposing a conductive pad on the bonding pad.

17. A method of manufacturing a semiconductor structure, comprising:
providing a substrate;
disposing a dielectric over the substrate;
forming a plurality of recesses on a sidewall of the substrate, wherein the plurality if recesses extend into the substrate;
forming a first capping layer over the sidewall of the substrate, the first capping layer being conformal to the sidewall of the substrate; and
forming a second capping layer over the first capping layer, the second capping layer being conformal to the first capping layer and separated from the substrate by the first layer.

18. The method of claim 17, wherein the first capping member includes a plurality of protrusions complementary with the plurality of recesses of the substrate.

19. The method of claim 17, wherein the plurality of recesses are spaced from each other in a distance substantially greater than 0.1um.

20. The method of claim 17, further comprising forming the first capping layer over a sidewall of the dielectric.
